(19) United States
(12) Patent Application Publication
(10) Pub. No.: US 2016/0324011 A1
(43) Pub. Date: Nov. 3, 2016

(54) Surface Coatings

(71) Applicant: EUROPLASMA NV, Oudenaarde (BE)

(72) Inventors: Filip Legein, Keerbergen (BE); Eva Rogge, Kruishoutem (BE); Peter Martens, Maarkedal (BE)

(21) Appl. No.: 15/103,367

(22) PCT Filed: Dec. 10, 2014
(86) PCT No.: PCT/EP2014/077233

§ 371 Date: Jun. 10, 2016

(30) Foreign Application Priority Data
Dec. 10, 2013 (GB) 1321792.2

(51) Int. Cl. H05K 3/28

(52) U.S. Cl. CPC H05K 3/285; H05K 3/282; H05K 2201/09872; H05K 2203/095

(57) ABSTRACT

The present invention concerns a process for the deposition of a solder-through polymer coating on an uncoated printed circuit board which comprises the use of an average low power and low pressure plasma polymerisation in a polymerisation chamber of an organosilane precursor monomer which is introduced into said polymerisation chamber by means of a carrier gas, said organosilane being of the Formula Y1-X—Y2 (I) or —[Si(CH3)2-X-]n- (II), wherein: X is O or NH; Y1 is —Si(Y3)(Y4)Y5; Y2 is Si(Y3′)(Y4′)Y5′; Y3, Y4, Y5, Y3′, Y4′, and Y5′ are each independently H or an alkyl group of up to 10 carbon atoms; the monomer of formula (II) is cyclic wherein n is 2 to 10, and wherein at most one of Y3, Y4 and Y5 is hydrogen, at most one of Y3′, Y4′ and Y5′ is hydrogen and the total number of carbon atoms is not more than 20.

The present invention relates to surface coatings and processes for their preparation. In particular it relates to substrates coated by a solder-through polymer layer and to the preparation of such layers by use of a monomer; and especially the use of such processes to form solder-through layers on a printed circuit board.

A printed circuit board (PCB) comprises an insulating material on which conductive tracks lie. The tracks are typically made of copper and function as wires between electrical components that are subsequently attached to the board, e.g. by soldering.

It is known in the art to coat PCBs and hence the tracks in order to protect the tracks from the environment, e.g. to inhibit or prevent oxidation of the tracks. Solder-through polymer coatings have been employed so that an electrical component may subsequently be connected to the tracks of a PCB without first having to remove the protective coating from the PCB.

Prior art methods of depositing a protective coating onto PCPs describe polymerising fluorocarbon gas monomers such as tetrafluoromethane (CF₄), hexafluroethane (C₂F₆), hexafluoropropylene (C₃F₆) or octafluoropropane (C₃F₈) using plasma deposition techniques. Such methods are described in WO 2008/102113.

However, this particular class of precursor molecules requires high power plasma techniques, for example, of 500 W for a 490 l plasma chamber, in order to initiate the polymerisation reaction. Moreover, such precursor molecules require high precursor gas flow rates, e.g. 100 sccm, and long deposition times, typically over 5 minutes, in order to obtain an acceptable thickness of the polymer deposition. For example, a deposition time of 7 minutes with the parameters mentioned above, will lead to a coating thickness of 28.4 nm.

A problem that may arise when using the known high monomer gas flow rates and or high power plasma is that the resultant polymer coatings have a non-uniform thickness. For instance, high power plasma causes monomers to fragment which can result in unpredictable deposition of the polymer and hence substandard coatings. Non-uniform deposition can lead to non-uniform thickness. This is disadvantageous because non-uniform thickness can produce areas which are thicker than optimal and so can be difficult to solder through and may generate areas of insufficient, or no coating coverage which then leave areas which can corrode. A more uniform coating is very important for high volume soldering operations, for example, because it gives more consistent solder joints with fewer defects.

Another problem that may arise when utilising precursor molecules such as those described above is that the subsequently formed polymer layer has limited hydrophobicity. Typical contact angles for water that can be achieved with such coatings can be not more than 90 degrees. But PCBs are often required in devices used in hostile environments, such as where corrosion or abrasion of the conductive tracks may lead to a shorter lifetime of the electrical circuit than would normally be wished. Therefore, it is desirable to provide a coating with higher levels of hydrophobicity, for example as demonstrated by higher contact angles for water of above 95 degrees, for example 100 degrees or more.

Another problem with methods employing fluorocarbons is that they lack means to control the rate in which precursor flows into the plasma chamber. Prior art methods typically adopt a “flow-through” process, which means that monomer is drawn in through an inlet port, flows through the plasma zone (i.e. the sample chamber) and is extracted through an exhaust port in a constant manner. As a consequence, the concentration of precursor is not homogenous throughout the chamber which may exacerbate non-uniformity of thickness.

Typical prior art coatings are often soft coatings with limited scratch resistance. Coatings deposited by polymerisation of fluorocarbon monomers tend to be yellowish, which may become visible after deposition. The present invention provides a hard coating and/or colourless and transparent coatings. Such hard coatings can have good scratch resistance.

Deposition of typical prior art coatings often produces harmful or toxic by-products. The monomer precursor or precursors used in the present invention, and thus the coating as well, are non-toxic and there are no toxic-by products formed during the coating.

Certain monomers used in the present invention have been employed in the formation of gas barrier coatings for use in the food industry. Such monomers have also been used in the formation of a protective insulation layer as described in U.S. Pat. No. 6,344,374 and have been employed to form a layer on top of a conductive film as described in WO2010/134446. Such prior art coatings are often deposited in complex multi-step processes, with the need of a adhesion layer to have sufficient adhesion of the gas barrier layer. This is described in WO2009/007654 and WO2012/171661.

The present invention provides a coating directly on to the substrate without the need for such an adhesion layer. Such coatings can also have a more uniform thickness across the substrate layer and are hydrophobic and scratch resistant.

The use of the new processes described herein can provide more resilient layers, layers with one or more of better in situ performance, no toxic by-products, increased uniformity, better solderability, thinness, improved wettability, improved water repellancy, improved scratch resistance and no colour change and transparency.

A first aspect of the invention provides a process for the deposition of a solder-through polymer coating on an uncoated printed circuit board, sometimes called a “bare printed circuit board”, which comprises the use of an average low power and low pressure plasma polymerisation in a polymerisation chamber of an organosilane precursor monomer which is introduced into said polymerisation chamber by means of a carrier gas, said organosilane being of the of formula (I) or (II)

Y₁—X—Y₂ (I) or

—[Si(CH₃)₂—X—]ₙ— (II)

wherein X is O or NH, Y₁ is —Si(Y₃)(Y₄)Y₅ and Y₂ is Si(Y_{3′})(Y_{4′})Y_{5′} wherein Y₃, Y₄, Y₅, Y_{3′}, Y_{4′}, and Y_{5′} are each independently H or an alkyl group of up to 10 carbon atoms; the monomer of formula (II) is cyclic wherein n is 2 to 10; wherein at most one of Y₃, Y₄ and Y₅ is hydrogen, at most one of Y_{3′}, Y_{4′} and Y_{5′} is hydrogen; and the total number of carbon atoms is not more than 20.

The alkyl groups may be straight or branched-chain but straight groups are preferred. Such alkyl groups are aptly methyl or ethyl groups of which methyl is preferred. Aptly all of Y₃, Y₄, Y₅, Y_{3′}, Y_{4′} or Y_{5′} are alkyl groups.

The monomer of Formula I may be one containing six methyl groups. Aptly the monomer of Formula I is hexamethyldisiloxane. Aptly the monomer of Formula I is hexamethyldisilazane.

The monomer of Formula II may be one wherein n is 3, or n is 4, or n is 5, or n is 6. Aptly the monomer of Formula II is octamethylcyclotetrasiloxane. Aptly the monomer of Formula II is hexamethylcyclotrisilazane.

Preferably the monomer employed in this invention is hexamethyldisiloxane.

The plasma polymerisation may be continuous wave polymerisation. The plasma polymerisation may be pulsed wave polymerisation.

Preferably, the organosilane precursor monomer is introduced to a plasma chamber by means of a carrier gas.

In some cases, the processes comprise an initial pre-treatment to clean and/or etch and/or activate the printed circuit board (PCB) prior to coating. A pre-treatment in the form of an activation and/or cleaning and/or etching step may be advantageous towards the adhesion and cross-linking of the polymer coating to the PCB in the case of substrates which are soiled or particularly inactive.

Adhesion of the polymer coating to the uncoated PCB substrate is important for the corrosion resistance of the coated surfaces. After manufacture of an uncoated PCB, it can contain varying amounts of residues derived from production and handling. These residues are mostly organic contamination or contamination in the form of oxides. When a soiled component is coated without a pre-treatment, a substantial part of the polymer coating binds with these residues, which may cause pinholes later on (unless the carrier gas is itself one such as oxygen that can provide the cleaning and/or etching and/or activating functions). The pre-treatment in the form of an activation and/or a cleaning and/or an etching removes the contamination and allows improved adhesion of the coating with the surface of the electronic component and/or device which is to be soldered to the PCB. An etching process can also be used to eliminate surface contamination of the copper prior to the coating step.

The skilled person will be able to determine whether or not a pre-treatment step is required, and this will depend upon factors such as the cleanliness of the substrate to be coated (which may in turn depend upon the cleanliness of the production area in which the substrate was manufactured).

Preferably, this pre-treatment is done using reactive gases, e.g. H₂, O₂, and etching reagents such as CF₄, but also inert gases, such as Ar, N₂ or He may be used. Mixtures of the foregoing gases may be used as well.

In particular embodiments of the invention that may be mentioned, the polymer deposition step is performed in the presence of a carrier gas, which may be the same gas (or mixture of gases) employed in the pre-treatment step.

Preferably the pre-treatment is done with O₂, Ar, or a mixture of O₂ and Ar, of which O₂ is presently favoured.

Preferably, the pre-treatment is performed from 15 seconds to 15 minutes, for example from 30 seconds to 10 minutes, preferably 45 seconds to 5 minutes, e.g. 5, 4, 3, 2, or 1 minutes. The duration of the pre-treatment depends on the precursor used, on the degree of contamination on the part to be treated, and on the equipment.

The power of the pre-treatment can be applied in continuous wave mode or in pulsed wave mode. When a pre-treatment is used, the polymer coating is applied in a next step, which may be carried out in the same equipment. If no pre-treatment is performed, the coating step is the first and only step of the whole process.

Preferably, a pre-treatment is performed prior to the coating step.

Preferably, the pre-treatment and the coating step are carried out in the same chamber without opening the chamber in between the steps, to avoid deposition of additional contamination from the atmosphere in between pre-treatment step and coating step.

Preferably, when applied in continuous wave mode in a 490 l big plasma chamber, the pre-treatment takes place at 5 to 5000 W, more preferably 25 to 4000 W, even more preferably at 50 to 3000 W, say 100 to 2500 W, such as 200 to 2000 W, e.g. 2000, 1900, 1800, 1750, 1700, 1600, 1500, 1400, 1300, 1250, 1200, 1100, 1000, 950, 900, 850, 800, 750, 700, 650, 600, 550, 500, 450, 400, 350, 300, 250, or 200 W.

Preferably, when applied in pulsed wave mode in a 490 l big plasma chamber, the pre-treatment takes place at a peak power value of 5 to 5000 W, more preferably 25 to 4000 W, even more preferably at 50 to 3000 W, say 100 to 2500 W, such as 200 to 2000 W, e.g. 2000, 1900, 1800, 1750, 1700, 1600, 1500, 1400, 1300, 1250, 1200, 1100, 1000, 950, 900, 850, 800, 750, 700, 650, 600, 550, 500, 450, 400, 350, 300, 250, or 200 W.

When applied in pulsed power mode, the pulse repetition frequency may be from 100 Hz to 10 kHz having a duty cycle from approximately 0.05 to 50%, with the optimum parameters being dependent on the gas or gas mixture used.

The solder-through polymer coating may be formed by deposition in a plasma chamber, the plasma chamber containing a first electrode set and a second electrode set, the first and second electrode sets being arranged to opposing sides of the chamber, wherein the first and second electrode sets comprise plural radiofrequency electrode layers and/or plural ground electrode layers.

Preferably, one or both of the first and second electrode sets comprise an inner electrode layer and a pair of outer electrode layers. An electrode set comprising an inner electrode layer and a pair of outer electrode layers might be called a “tri-electrode”.

Preferably, the inner electrode layer is a radiofrequency electrode layer and the outer electrode layers are ground electrode layers.

Alternatively, the inner electrode layer may be a ground electrode layer and the outer electrode layers may be radiofrequency electrode layers.

When the inner and/or outer electrode layer or electrode layers are of the radiofrequency type, the or each electrode layer may comprise a heat regulator, e.g. a substantially flat or channel portion for receiving a regulator fluid.

When the inner and/or outer electrode layer or electrode layers are of the ground type, the or each electrode layer need not comprise a heat regulator. Thus, electrode layers of this type may simply comprise a plate, mesh or other configuration suitable for generating the plasma.

Preferably, the heat regulator comprises hollow tubing. The hollow tubing may follow a path which curves upon itself by approximately 180° at regular intervals to provide an electrode that is substantially planar in dimension.

Preferably, the hollow tubing comprises a diameter of from approximately 2.5 to 100 mm, more preferably from approximately 5 to 50 mm, even more preferably from approximately 5 to 30 mm, say up to 25, 20 or 15 mm, for example 10 mm.

Preferably, the hollow tubing has a wall thickness of from approximately 0.1 to 10 mm, more preferably from approximately 0.25 to 5 mm, even more preferably from approximately 0.25 to 2.5 mm, say 1.5 mm.

Preferably, the distance between the hollow tubing before and after the curve is between 1 and 10 times the diameter of the tubing, say around 3 to 8, for example 5 times the diameter of the tubing.

Preferably, the hollow tubing comprises a conductive material such as a metal, e.g. aluminium, stainless steel or copper. Other suitable conductive materials may be envisaged.

Preferably, the hollow tubing is fed with a fluid such as a liquid such as water, oil or other liquids or combinations thereof.

Preferably, the fluid can be cooled or heated so that the plasma can be regulated over a wide temperature range, e.g. from 5 to 200° C.

Preferably, the fluid regulates the plasma at a temperature of from approximately 20 to 90° C., more preferably from approximately 25 to 75° C., even more preferably from approximately 30 to 60° C., such as 35 to 55° C.

Preferably, the plasma chamber is temperature controlled, e.g. to avoid temperature differentials within the chamber, and to avoid cold spots where the process gas can condense.

For instance, the door, and some or each wall(s) of the vacuum chamber may be provided with temperature control means.

Preferably, the temperature control means maintains the temperature from 15 to 70° C., more preferably from between 40 and 60° C.

Preferably, also the pump, the liquid monomer supply, the gas supply or supplies and all connections between those items and the plasma chamber are temperature controlled as well to avoid cold spots where the process gas or gases can condense.

Preferably, the power is applied across the radiofrequency electrode or electrodes via one or more connecting plates.

The power of the coating process may be applied in continuous wave mode or in pulsed power mode.

Preferably, when applied in continuous wave mode in a 490 l big plasma chamber, the applied power for the coating process is approximately 5 to 5000 W, more preferably 10 to 2000 W, even more preferably at 20 to 1500 W, say 250 to 1000 W, such as 50 to 750 W, e.g. 750, 725, 700, 675, 650, 625, 600, 575, 550, 525, 500, 475, 450, 425, 400, 375, 350, 325, 300, 275, 250, 225, 200, 175, 150, 125, 100, 95, 90, 85, 80, 75, 70, 65, 60, 55, or 50 W.

Preferably, for a chamber with a volume of 490 l, when applied in pulsed mode, the applied power for the coating process is approximately 5 to 5000 W, more preferably approximately 10 to 4000 W, even more preferably approximately, say 20 to 3000 W, for example 30 to 2500 W, say 50 to 2000 W, say 75 to 1500 W, say 100 to 1000 W, say 1000, 975, 950, 925, 900, 875, 850, 825, 800, 775, 750, 725, 700, 675, 650, 625, 600, 575, 550, 525, 500, 475, 450, 425, 400, 375, 350, 325, 300, 275, 250, 225, 200, 190, 180, 175, 170, 160, 150, 140, 130, 125, 120, 110, or 100 W.

For chambers with a higher volume, the applied power is typically slightly increased due to the larger surface area of the electrode sets due to the use of larger or more electrode layers.

When the power is applied in pulsed power mode, the pulse repetition frequency may be from 100 Hz to 10 kHz having a duty cycle from approximately 0.05 to 50%, with the optimum parameters being dependent on the monomer used.

The optimal power mode and power setting depends on the system used—its volume, size and number of electrode sets, and on the chemistry used.

Preferably, the radiofrequency electrode or electrodes generate a high frequency electric field at frequencies of from 20 kHz to 2.45 GHz, more preferably of from 40 kHz to 13.56 MHz, with 13.56 MHz being preferred.

Preferably, the plasma chamber comprises further electrode sets, for example third, fourth, fifth and sixth electrode sets and so on.

The or each further electrode set may comprise the same architecture as the first and second electrode sets.

Preferably, the plasma chamber further comprises locating and/or securing means such as one or more connecting plates and/or the chamber walls for locating a, the or each electrode at a desired location with the plasma chamber.

Preferably, the plasma chamber comprises one or more inlets for introducing a monomer mixed with a carrier gas to the plasma chamber. The carrier gas is used to strike the plasma.

Preferably, the plasma chamber comprises at least two inlets.

Preferably, each inlet feeds monomer mixed with carrier gas into a monomer-and-gas distribution system that distributes the mixture evenly across the chamber. For example, the inlet may feed into a manifold which feeds the chamber.

Each inlet may be spatially distinct. For instance, a first inlet may be provided in a first wall of the plasma chamber and a second inlet may be provided in a different wall to the first inlet, e.g. the opposite wall.

The apparatus also comprises a monomer vapour supply system. Monomer is vaporized in a controlled fashion. Controlled quantities of this vapour are fed into the plasma chamber preferably through a temperature controlled supply line.

Preferably, the monomer is vaporized at a temperature of from 20° C. to 120° C., more preferably from 30° C. to 90° C., the optimum temperature being dependent on the physical characteristics of the monomer. At least part of the supply line may be temperature controlled according to a ramped (either upwards or downwards) temperature profile. The temperature profile will typically be slightly upward from the point where the monomer is vaporized towards the end of the supply line. In the vacuum chamber the monomer will expand and the required temperatures to prevent condensation in the vacuum chamber and downstream to the pump will typically be lower than the temperatures of the supply line.

The apparatus also comprises a gas supply system for introducing a gas or more different gases, for example a carrier gas or a combination of carrier gases, together with the evaporated monomer into the vacuum chamber. A first canister containing the first gas is connected with a first mass flow controller (MFC) which controls the flow of gas. In some embodiments, a second canister containing a second gas is connected with a second mass flow controller (MFC). In yet another embodiment, a third canister containing a third gas is connected with a third mass flow controller (MFC), and so on.

After passing the mass flow controller, the or each gas is mixed with the monomer vapour before led into the vacuum chamber. In some embodiments, the gas supply line is heated after the mass flow controller to avoid temperature differences at the mixing point, which might lead to condensation of the monomer—carrier gas mixture.

Preferably, the sample chamber can receive or further comprises a perforated container or tray for receiving a substrate to be coated, e.g. a PCB.

Preferably, the substrate to be coated is located on or within the container or tray such that, in use, a polymer coating is applied to each surface of the substrate.

It is preferable that a minimum distance of a few mm, more preferably 10 to 100 mm, for example 15 to 90 mm, say less than 80, 70, 60 or 50 mm, most preferably 25 to 50 mm, is maintained between the outermost electrode set and the surface of the substrate to be coated.

Preferably, the polymer layer is a hydrophobic and scratch resistant polymer layer that can be soldered through, formed by polymerisation of the monomers described herein.

In the current invention, hydrophobic surfaces can be created with contact angles for water of more than 95 degrees. In some cases contact angles of more than 100 degrees are achieved.

A system comprising a plasma chamber as described herein may also be utilised to deposit the solder-through and scratch resistant polymer coating.

Preferably, the system comprises one or more gas outlets connected to the pump system.

Preferably, the system comprises at least two gas outlets.

Preferably, the or each gas outlet is positioned in a way that distributes the monomer evenly across the chamber. The gas outlets may communicate with a manifold.

Although we neither wish nor intend to be bound by any particular theory, we understand that the plasma created in between electrode sets of the apparatus cannot be described as either a pure primary or as a pure secondary plasma. Rather, we consider that the electrode sets create a new hybrid form of plasma which is strong enough to start and maintain a polymerisation reaction at very low power, but which at the same time is benign enough not to break down the reactive monomers.

As will be appreciated, a useful and unique aspect is that it is possible to establish a plasma on both sides of an article, e.g. a PCB, to be coated when positioned between two electrode sets. Moreover, the generated plasma has a similar, preferably the same, intensity on each side of the article, and hence will initiate the same or similar coating thickness.

The preferred method of deposition is low pressure plasma polymerisation.

By low pressure in this context it is meant that the pressure in a chamber up to 10000 l big, is a working pressure for plasma polymerisation such as less than 500 mTorr (66.7 Pa), preferably less than 250 mTorr (33.3 Pa), for example less than 150 mTorr (16.7 Pa).

Preferably, the method comprises applying a polymer coating having a thickness of from 10 to 500 nm, more preferably of from 10 to 200 nm, even more preferably of from 20 to 150 nm, e.g. most preferably of from 40 to 100 nm. The layer may be less than 500 nm, for example, less than 450, 400, 350, 300, 250, 200, 175, 150, 125, 100, 90, 80, 75, 70, 60, 50, 40 nm, e.g. 30 nm.

Preferably, the method comprises applying a polymer coating having a uniformity variation of the coating thickness of less than 10%.

The thickness and uniformity of the coating may depend upon a number of factors, including the duration of the deposition process, the nature of the monomer(s) employed, the flow rate of the monomer(s), the nature of the carrier gas (mixture) and its flow rate, the (mode of the) power applied during the process step or steps in case there is a pre-treatment step, the shape and size of the plasma chamber, the arrangement of the electrode layers within the electrode sets, the arrangement of the electrode sets within the chamber and/or the positioning of the uncoated printed circuit board relative to the electrode sets.

In any event, using the teaching of the present document, those skilled in the art will be able to identify through routine methods the parameters for the deposition process that, for any given plasma polymerisation chamber, is necessary to achieve coating thickness within a set range for each (combination of) organosilane monomer(s) and carrier gas(es).

In order to achieve a coating with a uniformity variation of the coating thickness of less than 10% with the method and the monomers as disclosed in this document, and more particularly as claimed in claim 1, a number of particularly preferred method steps and/or parameter values or parameter ranges are disclosed in this document.

With regard to the duration of the deposition process, typical deposition times are in the region of 15 seconds to 10 minutes, such as from 30 seconds to 5 minutes or, particularly, from 45 to 180 seconds. For example, when the organosilane monomer is hexamethyldisiloxane, the deposition time may be from 30 to 120 seconds, such as about 60 to 90 seconds.

The above deposition times may be employed in combination with any of the specific organosilane monomers, carrier gases, polymerisation chambers, electrode layer and set arrangement, (mode of) applied powers for the coating process, monomer feed arrangements and/or monomer flow rates described herein. Further, any processes involving these (combinations of) parameters may be performed either with or without a pre-treatment step as described herein.

Further, in particular embodiments of the invention, the uncoated printed circuit board (PCB) is positioned in the polymerisation chamber such that:
the PCB is placed between two electrode sets, each set positioned on opposite sides of the chamber, and wherein each set of electrodes comprise plural radiofrequency electrode layers and/or plural ground electrode layers; and
the distance from one side of the PCB to the electrode set positioned on that side of the PCB is approximately the same as (i.e. within 10% of, such as within 9, 8, 7, 6, 5, 4, 3, 2 or 1% of) the distance from the opposite side of the PCB to the electrode set on that opposite side.

Positioning the uncoated PCB in this manner relative to the electrode sets can help to ensure uniformity of the polymer coating on both sides of the PCB.

In the current invention, hydrophobic and scratch resistant surfaces can be created with contact angles for water of more than 95 degrees.

The method may comprise drawing a fixed flow of monomer into the plasma chamber using a monomer vapour supply system. The method may also comprise drawing one or more fixed flow or flow of gas, e.g. one or more carrier gases, into the plasma chamber using a mass flow controller. Preferably, monomer vapour and carrier gas/gases are mixed homogeneously before entering the vacuum chamber. A throttle valve in between the pump and the plasma chamber may adapt the pumping volume to achieve the required process pressure inside the plasma chamber.

Preferably the throttle valve is closed by more than 90% (i.e. to reduce the effective cross section in the supply conduit to 10% of its maximum value) in order to reduce the flow through the chamber and to allow the monomer and carrier gas/gases mixture to become evenly distributed throughout the chamber.

Once the monomer vapour pressure has stabilized in the chamber the plasma is activated by switching on the radiofrequency electrode layers.

Alternatively, the method may comprise introducing the monomer and carrier gas/gases mixture into the plasma chamber in a first flow direction; and switching the flow after a predetermined time, for example from 10 to 200 seconds, for example from 30 to 180, 40 to 150 seconds, for example less than 150, 140, 130, 120, 110, 100, 90, 80, 70, 60, 50, 40, 30 or 20 seconds to a second flow direction.

Preferably, further switching of the monomer and carrier gas mixture flow direction may be executed, e.g. flow may be switched back to the first flow direction or to one or more further flow directions.

Preferably, the monomer and carrier gas mixture may enter the plasma chamber in the first flow direction for between 20 to 80% of a single process time or 30 to 70% of the time or 40 to 60% of the time or 50% of the time.

Preferably, the monomer and carrier gas mixture may enter the plasma chamber in the second flow direction for between 20 to 80% of a single process time or 30 to 70% of the time or 40 to 60% of the time or 50% of the time.

Preferably, the process comprises the step of introducing the organosilane precursor monomer to the plasma chamber, by means of one or more carrier gases selected from H2, N2, O2, N2O, CH4, He or Ar, and/or any mixture of these gases. In one preferred process, a single carrier gas is used. This is most preferably O2 or Ar.

The gas mixture (vaporized precursor monomer mixed with carrier gas/gases) introduced to the chamber preferably comprises about 1% to about 50% carrier gas/gases. Preferably, the composition of carrier gas or carrier gas mixture introduced to the chamber comprises in total about 5% to about 30% carrier gas or carrier gas mixture, e.g. about 10% carrier gas or carrier gas mixture.

Preferably, the first and second flow directions flow in substantially opposite directions. For instance, during a process, a monomer—carrier gas mixture may be introduced into the plasma chamber via walls which are substantially opposite to each another.

Preferably, the coating is applied to one or more surfaces of the substrate.

In a yet further aspect, the invention provides a method for coating a substrate, e.g. a PCB, with a polymer layer, which method comprises subjecting a monomer to a low power continuous or pulsed wave plasma polymerisation technique, wherein the monomer is hereinbefore described.

In a further aspect, the invention provides the use of a monomer to form a solder-through, scratch resistant and transparent polymer coating when the monomer is subjected to a low pressure plasma polymerisation technique, wherein the monomer is as hereinbefore described.

In a yet further aspect, the invention provides a solder-through, scratch resistant and transparent polymer layer formed by depositing a monomer using a low power continuous or pulsed wave plasma polymerisation technique, wherein the monomer is as hereinbefore described.

Preferably, the solder-through polymer layer has hydrophobic and scratch-resistant properties as well. The coating is typically transparent and invisible for the human eye.

Preferably, no toxic by-products are formed during the deposition of the solder-through polymer layer.

In the current invention, hydrophobic surfaces can be created with contact angles for water of more than 95 degrees. In some cases contact angles of more than 100 degrees are achieved.

Advantages of the chamber, system and/or method include, but are not limited to, one or more of allowing highly reactive classes of monomer to polymerise under low power conditions; maximising diffusion of the monomer within the chamber to provide uniform coatings in quick time; minimising deleterious effects of process gas flow through the chamber; generating a benign plasma which, preferably, has the same intensity on both sides of a substrate such as a PCB; can be used in either low continuous power or pulsed power modes; including a mechanism for alternating the monomer flow during the deposition such that better uniformity is achieved; providing a means for accurately controlling the temperature to avoid undesirable temperature gradients.

In order that the invention may be more readily understood, it will now be described by way of example only and with reference to the accompanying drawings, in which:

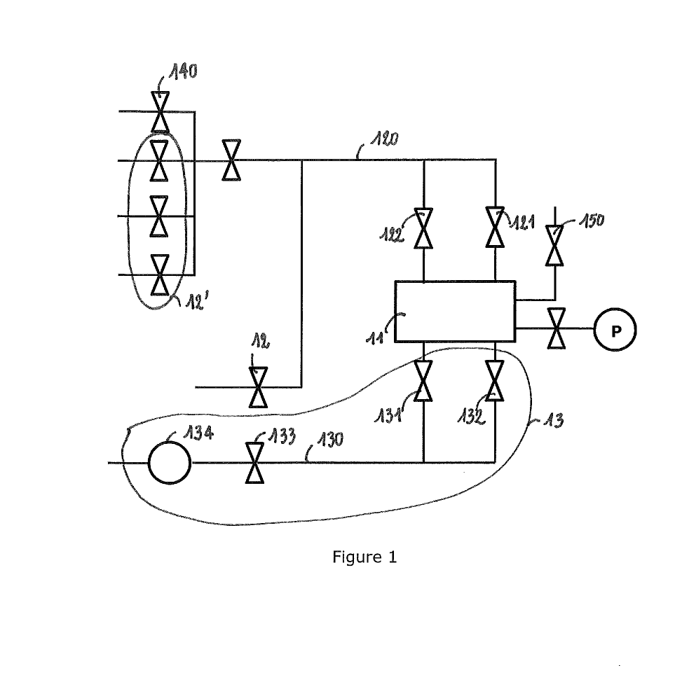

FIG. 1 shows a schematic representation of the configuration of the inlet, the vacuum chamber and the exhaust;

With reference to FIG. 1, a plasma deposition system will now be described. The system comprises a vacuum chamber 11 in communication with input apparatus 12 for introducing monomer and an input apparatus 12′ for introducing one or more gases via a common input line 120, and an exhaust apparatus 13 via an output line 130. The input apparatus 12 for introducing monomer into the vacuum chamber comprises in flow order a cartridge, first and second canisters, a baratron and a mass flow controller. The input apparatus 12′ for introducing one or more gases, for example one or more carrier gases, into the vacuum chamber comprises separately for each gas in flow order a canister containing the gas and a mass flow controller. After the respective mass flow controllers, the different gas supply lines come together in a single gas supply line. This gas supply line comes together with the monomer supply line in the supply line 120, also called input line. The mixture of monomer vapour and carrier gas/gases is introduced into the vacuum chamber 11 via the input line 120 and first 121 and second 122 chamber inlet valves. The exhaust apparatus 13 comprises in flow order first 131 and second 132 pump valves, a throttle valve 133, a roots and rotary pump 134 and an exhaust valve.

Within the vacuum chamber 11 there are multiple plasma electrode sets, e.g. four, arranged in stacked formation. Interposed between each plasma electrode set is a sample tray. The space between adjacent electrode sets is a sample chamber. In use, one or more PCBs are located on or within the sample tray. The sample tray is subsequently positioned between a pair of electrode sets within the vacuum chamber 11.

Once the sample tray is located within the vacuum chamber 11, the chamber 11 is evacuated and a gas mixture, containing a gaseous monomer (or a bespoke mixture of monomers) and one or more carrier gases, is introduced. Plasma is then activated within the chamber 11 by energising the electrode sets. The carrier gas is used to strike the plasma in order to initiate polymerisation of the monomer onto a surface of the PCB.

Referring back to FIG. 1, examples of deposition processes will now be described. Initially, the chamber 11 is reduced to a base level vacuum, typically 10 to 20 mTorr for a 490 l big chamber, by means of the pump 134 with the first 131 and second 132 pump valves open and the first 121 and second 122 chamber inlet valves closed. A quantity of monomer is transferred from the cartridge to the first canister by means of a feed pump. Typically, sufficient monomer for a single day of processing is transferred at once. The monomers used are preferably in liquid form. Sufficient monomer required for a single process run is then transferred from the first canister to the second canister via a metering pump. The temperature of the second canister and thus the monomer is raised, typically to between 30 and 90° C. in order to vaporise the monomer. The chosen temperature of the second canister is dependent on the vapour pressure of the monomer, which is measured by the heated vacuum gauge.

The or each carrier gas is transferred from its own canister, e.g. the gas bottle itself, through its own mass flow controller into a single gas supply line. The homogeneous gas mixture is transferred from the gas supply line into the inlet line 120, together with the vaporized monomer at the moment the monomer and carrier gas flow is needed.

In alternative embodiments, solid or gaseous monomer may be used. In embodiments where the monomer is a solid then it may also vaporised, e.g. by heating in a canister. In embodiments where the monomer is a gas then there is typically no need for vaporisation.

Once the target pressure within the vacuum chamber 11 is reached, typically between 40 to 50 mTorr for a 490 l big chamber, the first pump valve 131 is closed and the first chamber inlet valve 121 is opened. Consequently, when the monomer supply line valve is open, monomer vapour produced in the second canister passes through the mass flow controller and into the inlet line 120, where it is mixed with one or more carrier gases that have passed through their own mass flow controllers 12′. This gas mixture is introduced into the vacuum chamber 11 via the open chamber inlet valve 122. The pressure within the chamber 11 is regulated at a working level of typically 10 to 500 mTorr by either introduction of more monomer and more carrier gas or gasses, or by regulation of the throttle valve 133, which is typically a butterfly valve.

Once the pressure within the chamber 11 is stable, the electrode sets are activated to generate plasma within the chamber 11. Thus, the carrier gas strikes the plasma which activates the monomer and polymerisation occurs on one or more surfaces of the PCB. As such, polymerisation occurs rapidly even at low power and low monomer flow rates, typically 50 to 200 W and 50 to 100 standard cubic centimetres per min (sccm), respectively, for a 490 l big plasma chamber. Carrier gas is usually used at low flow rates, typically 5 to 30% of the monomer flow rate. Sufficient monomer is usually polymerised after approximately 60 to 300 seconds, to give a desired coating thickness of approximately 40 to 100 nm, depending on the process parameters chosen.

During the process, the direction of monomer flow through the chamber 11 is switched by control of the first 121 and second 122 chamber inlet valves and first 131 and second 132 pump valves. For example, for half the time the first chamber inlet valve 121 is open and the first pump valve 131 is closed (with the second chamber inlet valve 122 closed and second pump valve 132 open). For the remainder of the time, the second chamber inlet valve 122 is open and second pump valve 132 closed (with the first chamber inlet valve 121 closed and the first pump valve 131 open). This means that for half the time monomer flows from one side of the chamber 11 to another and for the remainder of the time vice versa. For example, for half the time monomer flows from the right to the left and for the remainder of the time monomer flows from the left to the right. The direction of monomer flow may be alternated one or more times during a single process run.

The inlet 120 and outlet 130 lines are separate from each other. The inlet line 120 may be coupled to a distribution system arranged to distribute gas across the chamber 11. The distribution system may be integrated on or within the wall of the chamber 11 so that it can be maintained at the same temperature as the chamber 11. Further, in preferred embodiments the outlet line 130 is typically arranged to be closer to the door of the chamber 11 (rather than the rear of the chamber) to compensate for the fact that the intensity of the plasma tends to be higher at regions closer to the electrode connection plates.

At the end of the process it is recommended for operator safety that the chamber inlet valves 121 and 122 are closed and the chamber outlet valves 131 and 132 are opened to reduce the chamber 11 pressure to base level to remove any residual monomer present. Once the base level is reached, the chamber outlet valves 131 and 132 are closed and the chamber inlet valves 121 and 122 are opened. An inert gas such as nitrogen is introduced from a separate canister by opening valve 140. The nitrogen is used as a purge fluid and is pumped away with the residual monomer. After completion of the purge, valve 140 is closed, the vacuum is removed and air is introduced into the chamber 11 by opening valve 150 until atmospheric pressure is achieved.

After one or more process cycles it is recommended to purge the monomer supply line with inert gas. An inert gas line can be connected to the or each canister to do this. It is preferable to purge the supply line straight to the pump (rather than via the chamber).

The applicant has discovered that use of an electrode set arrangement comprising an inner radiofrequency electrode layer and an outer pair of ground electrode layers further improves the uniformity of the deposited polymer coating.

The applicant has discovered that when organosilane polymer layers are deposited on a metal the deposited coating functions as a flux. This makes subsequent soldering operations easier.

This flux has a number of advantages, including
(i) removal of the coating to allow components to be soldered to the conductive tracks;
(ii) removal of any contamination from the copper tracks;
(iii) to prevent oxidation as the temperature is raised to the solder reflow point; and
(iv) to act as an interface between the liquid solder and the cleaned copper tracks.

It is not unusual for moisture and other gasses to be present within the structure of a PCB. If a polymeric coating is applied to a PCB, then this moisture becomes trapped and can cause various problems during soldering and also subsequently when the assembled PCBs are subjected to temperature variations. Trapped moisture may result in increased leakage currents and electromigration. Further, trapped moisture and/or other gases may hinder deposition of polymer in the parts of the substrate surface where the moisture and/or other gases are trapped.

It is essential to remove any trapped gases or moisture from the bare PCB; this also ensures good adhesion between the polymer coating and the PCB. Removal of trapped gasses or moisture can be carried out by baking the structure prior to placing it in a plasma chamber as in conventional conformal coating techniques. The inventive process described here enables this de-gassing, at least partially, to be carried out in the same chamber as the pre-treatment—cleaning and/or activation and/or etching—and the plasma polymerization.

The vacuum helps to remove moisture from the structure which improves the adhesion and prevents problems encountered in heat cycling during the lifetime of the products. The pressure range for degassing can be from 10 mTorr to 760 Torr with a temperature range from 5 to 200° C., and can be carried out for between 1 and 120 min, but typically for a few minutes.

The degassing, activation and/or cleaning and/or etching, and coating processes can all be carried out in the same chamber in sequence. An etching process can also be used to eliminate surface contamination of the copper prior to the activation and coating steps.

A further feature of the invention is that the abrasion resistance is improved compared to other organic coatings, giving improved performance in a number of applications such as connectors and other sliding contacts.

The conductive tracks on the substrate may comprise any conductive material including metals, conductive polymers or conductive inks. Conductive polymers are hydrophilic in nature, resulting in swelling, which can be eliminated by applying the coating described herein.

Solder resists are normally applied to PCB's during the manufacturing process, which serve to protect the metallic conductors from oxidation and to prevent the solder flowing up the metallic track, which would reduce the amount of solder in the joint. Solder resists also reduce the potential for solder shorts between adjacent conductors. Because the organosilane polymer coating is only removed where flux is applied, a very effective barrier to corrosion is left across the rest of the board, including the metallic conductors. This action also prevents the solder flowing up the track during the soldering process and minimises the potential for solder bridges between conductors. Consequently, in certain applications, the solder resist can be eliminated.

In order to further demonstrate features of the invention, reference is made to the following Examples.

### EXAMPLE 1

An experiment was run to coat a substrate using the parameters of Table 1.

TABLE 1
Process parameters according to a first example

| Parameter | Value |
|---|---|
| Liquid Monomer Supply (LMS) | |
| Temperature_canister | 30-50° C. |
| Temperature_LMS | 35-50° C. |
| Plasma Chamber | |
| Dimensions | 600 × 600 × 600 mm |
| Temperature wall | 40-60° C. |
| Electrodes & Generator | |
| Plasma | RF/ground |
| Power | 150-200 W |
| Frequency | 13.56 MHz |
| Frequency mode | cw |
| Monomer | Hexamethyldisiloxane |
| Flow | 50-100 sccm |
| Carrier gas | Oxygen (O₂) |
| Flow (% of monomer flow) | 5-20% |
| Pressure | |
| Base pressure | 10-20 mTorr |
| Work pressure | 45-55 mTorr |
| Contact angle | 100° |
| (ASTM D5964-04) | |

### Results

1. Water Repellence

The water contact angle according to ASTM D5964-04 is used to measure the hydrophobicity or wettability from a surface.

TABLE 2
Water repellence test data

| Precursor | C₃F₆ | Example 1 |
|---|---|---|
| Contact angle (°) | 90°-100° | 90°-110° |
| Process parameters | | |
| Time (minutes) | 10 | 2 |
| Work pressure (mTorr) | 70 | 50 |
| Power (W) | 500 | 200 |
| Flow (sccm) | 100 | 100 |

It is clear from Table 2 that the hydrophobicity, as measured by the contact angle, is equal to higher in the cases of the invention than for the prior art precursor. It is also noteworthy that the process time for the coatings of the invention, power and flow rate were all lower in developing the coatings of the invention than in the prior art case.

2. Transparent Coating

The colour change of coated objects has been measures according to ISO 105-J01-L*, a*, b*, c*, CMC 2:1. The results is expressed in a ΔE value. For coatings deposited according to the present invention, ΔE was below 1, meaning that no change of colour is noted with the visible eye.

3. Non-Toxic Coating

The coatings of the present invention are found to be non-toxic, tested according to ISO 10993.

4. Deposition Rate

To demonstrate the deposition rate of different coatings, the coating thickness was measured with ellipsometry after a certain treatment time on coated glass plates. The results are shown in Table 3 below.

TABLE 3
Deposition rate test data

| Precursor | C₃F₆ | Example 1 |
|---|---|---|
| Thickness (nm) | 28.4 | 32.5 |
| Process time (minutes) | 7 | 1 |
| Process parameters | | |
| Work pressure (mTorr) | 50 | 50 |
| Power (W) | 500 | 200 |
| Flow (sccm) | 100 | 100 |

The process time is approximately seven times higher for C₃F₆ than for the inventive coatings to deposit coating with a comparable thickness.

5. Uniformity of Coating for Single and Plural Electrodes

A conventional electrode set up was established with a single electrode layer per electrode set. In such conventional configurations the top side of the substrate or the side facing towards the radiofrequency (RF) electrode layer has a thicker coating formed thereon than the obverse face or face pointing to the ground electrode layer.

The multiple set up used in this example is composed of three electrode layers per electrode set: an inner RF electrode layer and a pair of outer ground electrode layers. The samples were placed between two electrode sets, wherein each set was positioned on either side of the samples.

TABLE 4
Uniformity test data

| | |
|---|---|
| Precursor | Hexamethyldisiloxane |

| | | |
|---|---|---|
| Electrodes/set | Single¹ | Multiple² |
| Thickness | | |
| Top (nm) | 65.1 | 64.2 |
| Bottom (nm) | 40.8 | 67.5 |
| Process parameters | | |
| Process time (minutes) | 2 | 2 |
| Work pressure (mTorr) | 50 | 50 |
| Power (W) | 200 | 150 |
| Flow (sccm) | 100 | 100 |

¹A single electrode system is one conventionally used in the prior art
²A multiple electrode system as described above

As can be seen in the above Table 4, the data demonstrates that the solder through coating of the invention covers markedly more consistent both surfaces of the substrate.

6. Coating Uniformity According to the Precursor

In order to determine the coating uniformity, process parameters were optimised for a prior art substance (C₃F₆) and a coating of the invention (Hexamethyldisiloxane).

The minimum standard deviation for the prior art substance was 25%. The standard deviation for the coating of the invention was 9.25%.

The coating of the invention was applied at a lower power than that of the prior art (ca. two-and-a-half to fife times less). It was also coated with a reduced treatment time.

7. Solderability from Plasma Coated PCB

Different coating thicknesses were evaluated regarding the solderability. For coatings of the invention (e.g. Hexamethyldisiloxane) (in pulsed or continuous power mode) the PCB joints soldered well. It was found that a wide range of coating thicknesses, in this experiment from 10 to 170 nm, showed good solderability.

8. Corrosion Resistance

To test the corrosion resistance, a single gas verification test according to DIN EN ISO 3231 was used. This test had been developed as a quick and effective method of evaluating gold and nickel coatings on copper.
The samples were placed in a chamber that had been filled with H₂SO₃ and the chamber was then placed in an oven at 40° C.
After 24 hours the samples were removed from the chamber and photographed.
The samples were replaced in the chamber which was refilled with a fresh charge of H₂SO₃. The chamber was put back in the oven and the temperature increased to 45° C. The chamber was kept at this temperature for a further four days, when some limited corrosion started to appear on the polymer coated samples.
Further photographs of the samples were taken at the end of the test.

The result shows that after 24 hours the ENIG-reference PCB was showing sufficient corrosion to make it unusable whereas the coatings of the invention (Example 1 above), plasma treated samples, showed no signs of corrosion. After a further four days, the ENIG reference sample was heavily corroded with large areas of copper oxide and nickel showing through. By contrast, the coating of the invention (Examples 1 above) showed no corrosion at all or just some tiny spots. In this experiment different precursor types, different coating thickness as well as different power modes (continuous or pulsed) showed the same excellent results.

1-29. (canceled)

30. A process for the deposition of a solder-through polymer coating on an uncoated printed circuit board which comprises the use of an average low power and low pressure plasma polymerisation in a polymerisation chamber of an organosilane precursor monomer which is introduced into said polymerisation chamber by means of a carrier gas, said organosilane being of the Formula (I) or (II)
Y₁—X—Y₂ (I) or
—[Si(CH₃)₂—X—]ₙ— (II)
wherein:
X is O or NH;
Y₁ is —Si(Y₃)(Y₄)Y₅;
Y₂ is Si(Y_{3′})(Y_{4′})Y_{5′};
Y₃, Y₄, Y₅, Y_{3′}, Y_{4′}, and Y_{5′}, are each independently H or an alkyl group of up to 10 carbon atoms;
the monomer of formula (II) is cyclic wherein n is 2 to 10,
wherein at most one of Y₃, Y₄ and Y₅ is hydrogen, at most one of Y_{3′}, Y_{4′}, and Y_{5′}, is hydrogen and the total number of carbon atoms is not more than 20,
and whereby the carrier gas is used to strike the plasma to activate the monomer.

31. A process according to claim 30, wherein X is O.

32. A process according to claim 30, wherein the deposited polymer coating comprises a water contact angle of more than 95 degrees.

33. A process according to claim 30, wherein a gas mixture of vaporized precursor monomer and one or more carrier gasses is introduced in the chamber wherein the gas mixture comprises 1% to 50% of said carrier gases, preferably wherein monomer vapour and carrier gas or carrier gases are mixed homogeneously before entering the polymerisation chamber.

34. A process according to claim 30, wherein said carrier gas is selected from H₂, N₂, O₂, N₂O, CH₄, He or Ar, and/or any mixture of these gases, preferably wherein a single carrier gas is used, preferably O₂ or Ar.

35. A process according to claim 30, wherein each alkyl group present in the organosilane of Formula (I) is a straight-chain alkyl group.

36. A process according to claim 30, wherein all of Y₃, Y₄, Y₅, Y_{3′}, Y_{4′}, or Y_{5′}, are alkyl groups, preferably wherein each alkyl group that Y₃, Y₄, Y₅, Y_{3′}, Y_{4′}, and/or Y_{5′}, may represent is methyl or ethyl, preferably wherein the organosilane monomer of Formula I is hexamethyldisiloxane or hexamethyldisilazane.

37. A process according to claim 30, wherein the processes further comprise a pre-treatment step to clean and/or etch and/or activate the printed circuit board (PCB) prior to polymer coating, preferably wherein the pre-treatment is effected using H₂, O₂, N2O, CH4, CF₄, He, Ar, N₂, He, a mixture of O₂ and CF₄, a mixture of O₂ and Ar, or mixtures thereof, preferably
wherein the pre-treatment is performed from 15 seconds to 15 minutes, such as 45 seconds to 5 minutes, using radiofrequency power applied in either continuous wave or pulsed wave mode, preferably wherein the pre-treatment and coating steps are carried out in the same chamber, without opening the chamber in between the steps.

38. A process according to claim 30, wherein the solder-through polymer coating is formed by deposition in a plasma chamber, the plasma chamber containing a first electrode set and a second electrode set, the first and second electrode sets being arranged to opposing sides of the chamber, wherein the first and second electrode sets comprise plural radiofrequency electrode layers and/or plural ground electrode layers, preferably wherein one or both of the first and second electrode sets comprise an inner electrode layer and a pair of outer electrode layers, more preferably wherein the inner electrode layer is a radiofrequency electrode layer or a ground electrode layer and the outer electrode layers are respectively ground electrode layers or radiofrequency electrode layers.

39. A process according to claim 38, wherein one or both of the first and second electrode sets comprise an inner electrode layer and a pair of outer electrode layers, wherein:
the inner electrode layer is a ground electrode layer and the outer electrode layers are radiofrequency electrode layers; or
the inner and/or outer electrode layer or electrode layers are of the radiofrequency type and the or each radiofrequency electrode layer comprises a heat regulator.

40. A process according to claim 30 which comprises applying a polymer coating having a thickness of from 10 to 500 nm, such as from 40 to 100 nm, preferably less than 90 nm, 80 nm, 75 nm, 70 nm, 60 nm, 50 nm, and/or wherein the duration of the polymer deposition process is from 15 seconds to 10 minutes, such as from 30 seconds to 5 minutes.

41. A process according to claim 30, wherein the uncoated printed circuit board (PCB) is positioned in the polymerisation chamber such that:
the PCB is positioned between two sets of electrodes, each set being positioned on opposite sides of the chamber, and wherein each set of electrodes comprise plural radiofrequency electrode layers and/or plural ground electrode layers; and
the distance from one side of the PCB to the electrode set positioned on that side of the PCB is within 10% of the distance from the opposite side of the PCB to the electrode set on that opposite side.

42. A process according to claim 40, which comprises applying a polymer coating having a thickness of less than 90 nm, and having a uniformity variation of the coating thickness of less than 10%.

43. Printed circuit board comprising a solder-through plasma polymerised coating having a uniformity variation of the coating thickness of less than 10%, said coating obtained by plasma polymerisation of an organosilane precursor monomer in a polymerisation chamber, wherein said organosilane precursor monomer is of the Formula (I) or (II)
Y1-X—Y2 (I) or
—[Si(CH3)2-X-]n- (II)
wherein:
X is O or NH;
Y1 is —Si(Y3)(Y4)Y5;
Y2 is Si(Y3′)(Y4′)Y5′;
Y3, Y4, Y5, Y3′, Y4′, and Y5′ are each independently H or an alkyl group of up to 10 carbon atoms;
the monomer of formula (II) is cyclic wherein n is 2 to 10,
wherein at most one of Y3, Y4 and Y5 is hydrogen, at most one of Y3′, Y4′ and Y5′ is hydrogen and the total number of carbon atoms is not more than 20,
wherein the organosilane precursor monomer is introduced in the polymerisation chamber by means of a carrier gas, and whereby said carrier gas is used to strike the plasma to activate the monomer and initiate polymerization onto one or more surfaces of the PCB.

44. Printed circuit board according to the claim 43, wherein said coating is applied essentially completely over at least one side of the printed circuit board, preferably essentially completely over both sides of the printed circuit board.
